(19) United States
(12) Patent Application Publication
(10) Pub. No.: US 2023/0380248 A1
(43) Pub. Date: Nov. 23, 2023

(54) DISPLAY DEVICE

(71) Applicant: Japan Display Inc., Tokyo (JP)

(72) Inventors: Hayata AOKI, Tokyo (JP); Masumi NISHIMURA, Tokyo (JP)

(73) Assignee: Japan Display Inc., Tokyo (JP)

(21) Appl. No.: 18/361,939

(22) Filed: Jul. 31, 2023

Related U.S. Application Data
(63) Continuation of application No. PCT/JP2022/000022, filed on Jan. 4, 2022.

(30) Foreign Application Priority Data
Feb. 1, 2021 (JP) 2021-014315

(51) Int. Cl. H10K 59/80

(52) U.S. Cl. CPC H10K 59/878

(57) ABSTRACT

According to one embodiment, a display device includes a substrate, a first lower electrode and a second lower electrode arranged on the substrate, a first organic layer including a light emitting layer and arranged on the first lower electrode, a second organic layer including a light emitting layer and arranged on the second lower electrode, a first upper electrode arranged on the first organic layer, a second upper electrode arranged on the second organic layer and separated from the first upper electrode, and a reflective layer arranged between the first upper electrode and the second upper electrode.

### CROSS-REFERENCE TO RELATED APPLICATIONS

This application is a Continuation Application of PCT Application No. PCT/JP2022/000022, filed Jan. 4, 2022 and based upon and claiming the benefit of priority from Japanese Patent Application No. 2021-014315, filed Feb. 1, 2021, the entire contents of all of which are incorporated herein by reference.

### FIELD

Embodiments described herein relate generally to a display device.

### BACKGROUND

Recently, display devices with organic light-emitting diodes (OLEDs) applied thereto as display elements have been put into practical use. Such a display element comprises an organic layer between a pixel electrode and a common electrode. The organic layer includes functional layers such as a hole-transport layer and an electron-transport layer in addition to a light emitting layer. Such an organic layer is formed by, for example, vacuum vapor deposition.

For example, in mask deposition, a fine mask including apertures corresponding to respective pixels is applied. However, formation accuracy of a thin film formed by deposition may be degraded due to processing accuracy of the fine mask, deformation of the aperture shape, and the like. For example, when an organic layer having a plurality of functional layers stacked is formed, an end surface of the organic layer is not formed at a desired position, which may lead to the degradation in performance of the display elements.

### BRIEF DESCRIPTION OF THE DRAWINGS

FIG. 1 is a view showing a configuration example of a display device DSP according to the embodiment.

FIG. 2 is a view showing an example of a configuration of the display element 20.

FIG. 3 is a plan view showing an example of layout of the sub-pixels SP shown in FIG. 1.

FIG. 4 is a plan view showing an example of a reflective layer RF which can be applied to the display portion DA shown in FIG. 3.

FIG. 5 is a cross-sectional view taken along line A-B shown in FIG. 4.

FIG. 6 is another cross-sectional view taken along line A-B shown in FIG. 4.

FIG. 7 is a plan view showing another example of the reflective layer RF which can be applied to the display portion DA shown in FIG. 3.

FIG. 8 is another cross-sectional view taken along line A-B shown in FIG. 7.

### DETAILED DESCRIPTION

Embodiments described herein aim to provide a display device with a desirable quality.

In general, according to one embodiment, a display device comprises a substrate, a first lower electrode and a second lower electrode arranged on the substrate, a first organic layer including a light emitting layer and arranged on the first lower electrode, a second organic layer including a light emitting layer and arranged on the second lower electrode, a first upper electrode arranged on the first organic layer, a second upper electrode arranged on the second organic layer and separated from the first upper electrode, and a reflective layer arranged between the first upper electrode and the second upper electrode.

According to the embodiments, a display device with a desirable quality can be provided.

Embodiments will be described hereinafter with reference to the accompanying drawings.

The disclosure is merely an example, and proper changes within the spirit of the invention, which are easily conceivable by a person of ordinary skill in the art, are included in the scope of the invention as a matter of course. In addition, in order to make the description clearer, the widths, thicknesses, shapes and the like, of the respective parts are schematically illustrated in the drawings, compared to the actual modes, in some cases. However, the schematic illustration is merely an example, and adds no restriction to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction along the X-axis is referred to as an X-direction or a first direction, a direction along the Y-axis is referred to as a Y-direction or a second direction, and a direction along the Z-axis is referred to as a Z-direction or a third direction. A plane defined by the X-axis and the Y-axis is referred to as an X-Y plane. Viewing the X-Y plane is referred to as plan view.

The display device DSP according to the embodiment is an organic electroluminescent display device comprising organic light emitting diodes (OLED) as display elements, and is mounted on televisions, personal computers, mobile terminals, mobile phones, and the like. The display element described below can be applied as a light emitting element of an illumination device, and the display device DSP can be applied to other electronic devices such as an illumination device.

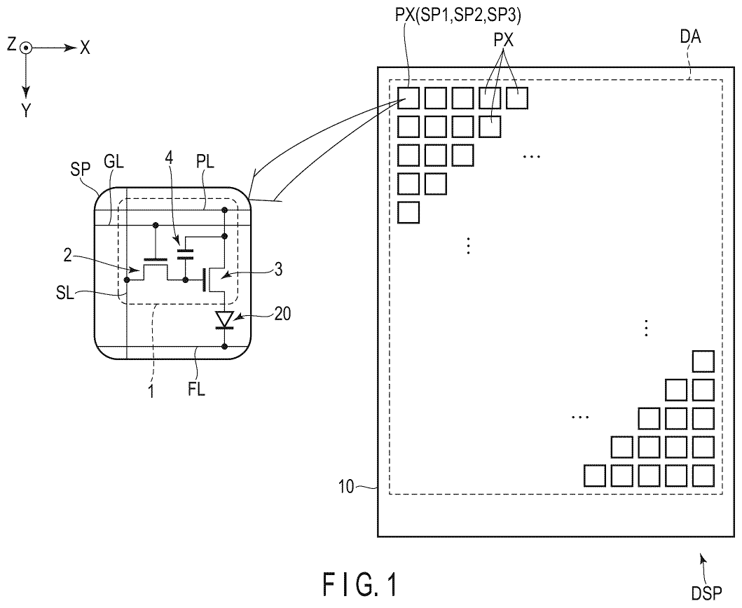

FIG. 1 is a view showing a configuration example of the display device DSP according to the embodiment. The display device DSP comprises a display portion DA where images are displayed, on an insulating substrate 10. The substrate 10 may be glass or a flexible resin film.

The display portion DA comprises a plurality of pixels PX arrayed in a matrix in the first direction X and the second direction Y. The pixel PX comprises a plurality of sub-pixels SP1, SP2, and SP3. As an example, the pixel PX comprises a red sub-pixel SP1, a green sub-pixel SP2, and a blue sub-pixel SP3. In addition to the sub-pixels of the above three colors, the pixel PX may comprise four or more sub-pixels including a sub-pixel of the other color such as white.

A configuration example of one sub-pixel SP included in the pixel PX will be described simply.

In other words, the sub-pixel SP comprises a pixel circuit 1 and a display element 20 driven and controlled by the pixel circuit 1. The pixel circuit 1 comprises a pixel switch 2, a drive transistor 3, and a capacitor 4. The pixel switch 2 and the drive transistor 3 are, for example, switch elements constituted by thin-film transistors.

In the pixel switch 2, a gate electrode is connected to a scanning line GL, a source electrode is connected to a signal line SL, and a drain electrode is connected to one of electrodes constituting the capacitor 4 and a gate electrode of the drive transistor 3. In the drive transistor 3, a source electrode is connected to the other electrode constituting the capacitor 4 and a power line PL, and a drain electrode is connected to an anode of the display element 20. A cathode of the display element 20 is connected to a power supply line FL. The configuration of the pixel circuit 1 is not limited to the example shown in the figure.

The display element 20 is an organic light emitting diode (OLED) which is a light emitting element. For example, the sub-pixel SP1 comprises a display element that emits light corresponding to a red wavelength, the sub-pixel SP2 comprises a display element that emits light corresponding to a green wavelength, and the sub-pixel SP3 comprises a display element that emits light corresponding to a blue wavelength. The pixel PX can realize multicolor display by comprising a plurality of sub-pixels SP1, SP2, and SP3 of different display colors.

However, the pixel PX may also be configured such that the display element 20 of each of the sub-pixels SP1, SP2, and SP3 emits light of the same color. Monochromatic display can be thereby realized.

In addition, when the display element 20 of each of the sub-pixels SP1, SP2, and SP3 is configured to emit white light, a color filter opposed to the display element 20 may be arranged. For example, the sub-pixel SP1 may comprise a red color filter opposed to the display element 20, the sub-pixel SP2 may comprise a green color filter opposed to the display element 20, and the sub-pixel SP3 may comprise a blue color filter opposed to the display element 20. Multicolor display can be thereby realized.

Alternatively, when the display element 20 of each of the sub-pixels SP1, SP2, and SP3 is configured to emit ultraviolet light, multicolor display can be realized by arranging a light conversion layer opposed to the display element 20.

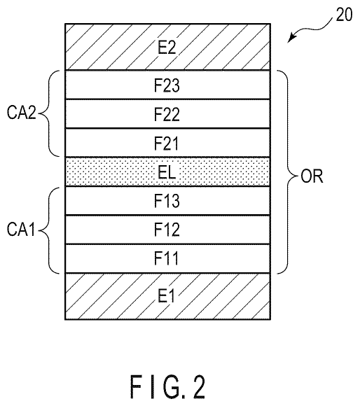

FIG. 2 is a view showing an example of a configuration of the display element 20.

The display element 20 comprises a lower electrode (first electrode) E1, an organic layer OR, and an upper electrode (second electrode) E2. The organic layer OR includes a carrier adjustment layer CA1, a light emitting layer EL, and a carrier adjustment layer CA2. The carrier adjustment layer CA1 is located between the lower electrode E1 and the light emitting layer EL, and the carrier adjustment layer CA2 is located between the light emitting layer EL and the upper electrode E2. The carrier adjustment layers CA1 and CA2 include a plurality of functional layers.

An example in which the lower electrode E1 corresponds to an anode and the upper electrode E2 corresponds to a cathode will be described.

The carrier adjustment layer CA1 includes a hole injection layer F11, a hole transport layer F12, an electron blocking layer F13, and the like, as functional layers. The hole injection layer F11 is arranged on the lower electrode E1, the hole transport layer F12 is arranged on the hole injection layer F11, the electron blocking layer F13 is arranged on the hole transport layer F12, and the light emitting layer EL is arranged on the electron blocking layer F13.

The carrier adjustment layer CA2 includes a hole blocking layer F21, an electron transport layer F22, an electron injection layer F23, and the like, as functional layers. The hole blocking layer F21 is arranged on the light emitting layer EL, the electron transport layer F22 is arranged on the hole blocking layer F21, the electron injection layer F23 is arranged on the electron transport layer F22, and the upper electrode E2 is arranged on the electron injection layer F23.

In addition to the functional layers described above, the carrier adjustment layers CA1 and CA2 may also include the other functional layers such as a carrier generation layer as needed or at least one of the above functional layers may be omitted in the carrier adjustment layers CA1 and CA2.

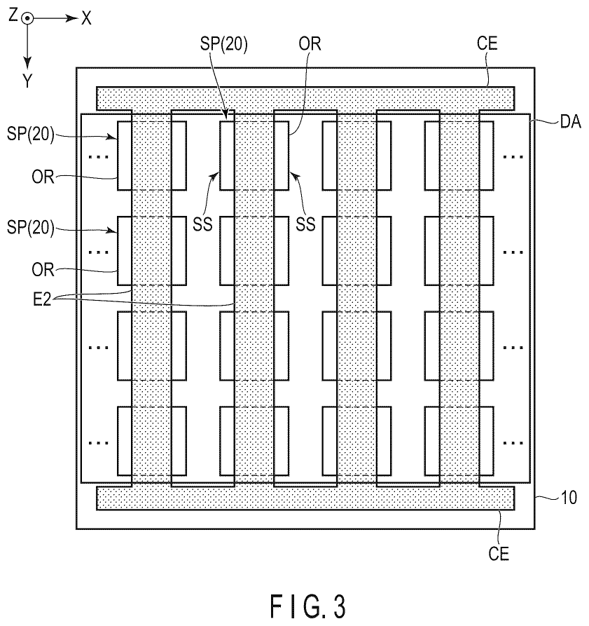

FIG. 3 is a plan view showing an example of layout of the sub-pixels SP shown in FIG. 1.

The sub-pixels SP are arrayed in a matrix in the first direction X and the second direction Y in the display portion DA. The organic layer OR and the upper electrode E2 of the display element 20 included in the sub-pixel SP are illustrated, and the illustration of the lower electrode is omitted. Although the organic layer OR is illustrated in a substantially square shape, the outer shape of the organic layer OR is shown in a simplified manner and does not necessarily reflect the actual shape.

Each of the organic layers OR is formed in an island shape and separated from each other. The organic layer OR has an end surface SS extending in the second direction Y. For example, a movement direction (or scanning direction) of a vapor deposition source in a case where the organic layer OR is formed by vapor deposition is the first direction X, and the end face SS is a plane intersecting with the movement direction.

The upper electrodes E2 are formed in a strip shape extending in the second direction Y and arranged at intervals in the first direction X, at the display portion DA. In one example, one upper electrode E2 is arranged over a plurality of organic layers OR arranged in the second direction Y. However, the upper electrode E2 does not overlap both end surfaces SS of each organic layer OR. The strip-shaped upper electrodes E2 are electrically connected to each other by a common line CE outside the display portion DA.

However, the movement direction (or scanning direction) of the vapor deposition source may be the second direction Y. In addition, the upper electrodes E2 may be formed in a strip shape extending in the first direction X and arranged at intervals in the second direction Y, at the display portion DA.

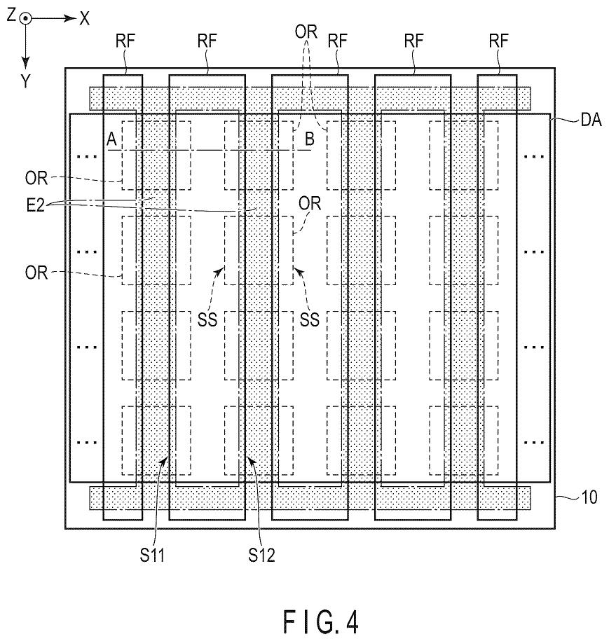

FIG. 4 is a plan view showing an example of a reflective layer RF which can be applied to the display portion DA shown in FIG. 3. In FIG. 4, the organic layer OR is represented by a dotted line, the upper electrode E2 is represented by a one-dot chain line, and the reflective layer RF is represented by a solid line.

The reflective layer RF is formed in a strip shape extending along the second direction Y in the display portion DA. The reflective layers RF are arranged at intervals in the first direction X. Each of the reflective layers RF has a first side surface S11 and a second side surface S12. The first side surface S11 and the second side surface S12 extend along the second direction Y and face each other in the first direction X.

The reflective layer RF is arranged between the upper electrodes E2 adjacent to each other in the first direction X, in plan view. In the example shown in FIG. 4, the reflective layer RF is arranged across the upper electrodes E2 adjacent in the first direction X. In other words, one upper electrode E2 of the upper electrodes E2 adjacent in the first direction X, overlaps the first side surface S11, and the other upper electrode E2 overlaps the second side surface S12. In addition, the reflective layer RF overlaps the end surface SS of each organic layer OR. Furthermore, each of the first side surface S11 and the second side surface S12 overlaps the plurality of organic layers OR arranged in the second direction Y. The reflective layer RF may be formed over the entire display portion DA.

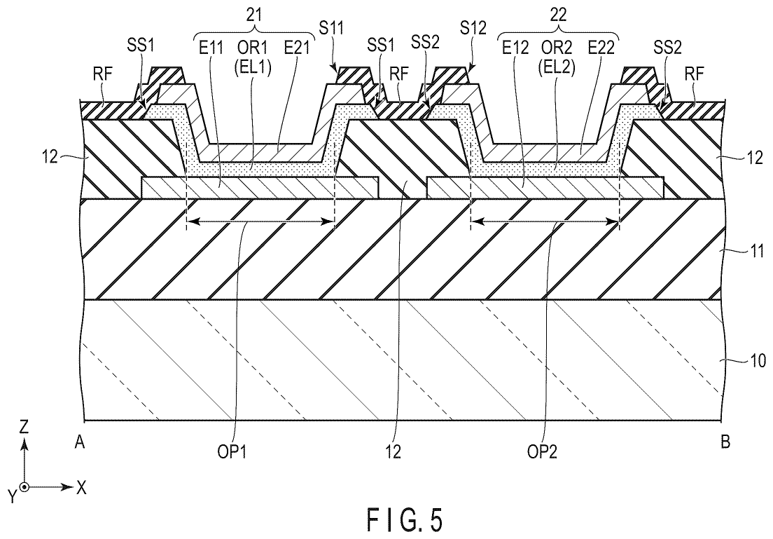

FIG. 5 is a cross-sectional view taken along line A-B shown in FIG. 4.

Two display elements adjacent in the first direction X will be focused. The display element located on the left side of the drawing is referred to as a display element 21, and the display element located on the right side of the drawing is referred to as a display element 22, for convenience.

The display element 21 comprises a lower electrode (first lower electrode) E11, an organic layer (first organic layer) OR1, and an upper electrode (first upper electrode) E21.

The display element 22 comprises a lower electrode (second lower electrode) E12, an organic layer (second organic layer) OR2, and an upper electrode (second upper electrode) E22.

The insulating layer (first insulating layer) 11 corresponds to an underlying layer of the display elements 21 and 22. The insulating layer (second insulating layer) 12 is arranged on the insulating layer 11. The insulating layers 11 and 12 are, for example, organic insulating layers.

The lower electrodes E11 and E12 are arranged on the insulating layer 11 and are arranged at intervals in the first direction X. Each of the lower electrodes E11 and E12 is the electrode arranged for each sub-pixel or each display element, and is electrically connected to the drive transistor 3 shown in FIG. 1. The lower electrodes E11 and E12 are referred to as pixel electrodes, anodes, or the like in some cases.

The lower electrodes E11 and E12 are transparent electrodes formed of, for example, a transparent conductive material such as indium tin oxide (ITO) or indium zinc oxide (IZO). The lower electrodes E11 and E12 may be metal electrodes formed of a metal material such as silver or aluminum. Alternatively, the lower electrodes E11 and E12 may be stacked layer bodies of transparent electrodes and metal electrodes. For example, the lower electrodes E11 and E12 may be constituted as stacked layer bodies formed by stacking a transparent electrode, a metal electrode, and a transparent electrode, in this order, or may be constituted as stacked layer bodies of three or more layers.

The insulating layer 12 is arranged between the lower electrode E11 and the lower electrode E12. In addition, the insulating layer 12 includes an opening OP1 and an opening OP2. The insulating layer 12 is formed to partition sub-pixels or display elements 21 and 22, and is referred to as a rib, partition, a bank, or the like in some cases.

The opening OP1 is a through hole which is formed in an area overlapping the lower electrode E11 and which penetrates the insulating layer 12 to the lower electrode E11. A peripheral part of the lower electrode E11 is covered with the insulating layer 12, and a central part of the lower electrode E11 is exposed from the insulating layer 12 at the opening OP1.

The opening OP2 is a through hole which is formed in an area overlapping with the lower electrode E12 and which penetrates the insulating layer 12 to the lower electrode E12. A peripheral part of the lower electrode E12 is covered with the insulating layer 12, and a central part of the lower electrode E12 is exposed from the insulating layer 12 at the opening OP2.

The organic layer OR1 includes a light emitting layer EL1. The organic layer OR1 is arranged at the opening OP1 to cover the lower electrode E11.

The organic layer OR2 includes a light emitting layer EL2. The light emitting layer EL2 may be formed of the same material as the light emitting layer EL1 (the organic layer OR1 and the organic layer OR2 emit light of the same color) or may be formed of a material different from that of the light emitting layer EL1 (the organic layer OR1 and the organic layer OR2 emit light of different colors). The organic layer OR2 is arranged at the opening OP2 to cover the lower electrode E12. On the insulating layer 12, the organic layer OR2 is separated from the organic layer OR1. The end surface SS1 of the organic layer OR1 and the end surface SS2 of the organic layer OR2 are opposed to each other on the insulating layer 12 and are arranged at an interval in the first direction X.

The upper electrode E21 is stacked on the organic layer OR1. A part of the organic layer OR1, which is located between the lower electrode E11 and the upper electrode E21, not through the insulating layer 12, can form a light emitting area of the display element 21. A part of the organic layer OR1, which is located between the insulating layer 12 and the upper electrode E21, hardly emits light. In addition, in the example shown in FIG. 5, the upper electrode E21 exposes the end surface SS1 of the organic layer OR1.

The upper electrode E22 is stacked on the organic layer OR2. The upper electrode E22 is separated from the upper electrode E21. A part of the organic layer OR2, which is located between the lower electrode E12 and the upper electrode E22, not through the insulating layer 12, can form a light emitting area of the display element 22. A part of the organic layer OR2, which is located between the insulating layer 12 and the upper electrode E22, hardly emits light. In addition, in the example shown in FIG. 5, the upper electrode E22 exposes the end surface SS2 of the organic layer OR2.

These upper electrodes E21 and E22 are electrodes arranged for each sub-pixel or each display element, and are electrically connected to each other by the common line CE outside the display portion DA, as described with reference to FIG. 3. The upper electrodes E21 and E22 are referred to as common electrodes, counter-electrodes, cathodes or the like in some cases.

The upper electrodes E21 and E22 are transflective electrodes and contain, for example, at least one metal material of magnesium, silver, aluminum, and gold. The upper electrodes E21 and E22 may be transparent electrodes formed of a transparent conductive material such as ITO or IZO. Alternatively, the upper electrodes E21 and E22 may be stacked layer bodies of transparent electrodes and metal electrodes.

In one example, the thickness of the organic layer OR1 along the third direction Z is set such that the peak wavelength of the emission spectrum in the light emitting layer EL1 matches the effective optical path length between the lower electrode E11 and the upper electrode E21. A microcavity structure for obtaining a resonance effect is thereby realized. Similarly, the thickness of the organic layer OR2 along the third direction Z is set such that the peak wavelength of the emission spectrum in the light emitting layer EL2 matches the effective optical path length between the lower electrode E12 and the upper electrode E22.

The reflective layer RF arranged between the display element 21 and the display element 22 is in contact with the end surface SS1 of the organic layer OR1 and the end portion of the upper electrode E21, and is in contact with the end surface SS2 of the organic layer OR2 and the end portion of the upper electrode E22. In addition, the reflective layer RF is in contact with the insulating layer 12 at a position between the end surface SS1 and the end surface SS2. The first side surface S11 of the reflective layer RF overlaps the upper electrode E21 outside the opening OP1. In addition, the second side surface S12 of the reflective layer RF overlaps the upper electrode E22 outside the opening OP2.

Such a reflective layer RF is an insulator having a surface resistivity of, for example, 10⁸Ω/□ or more. In other words, even if the reflective layer RF is in contact with the upper electrode or the organic layer, the reflective layer RF does not form an undesirable current leakage path.

The reflectance of the reflective layer RF is desirably equal to the reflectance of the upper electrode E2, which is a transflective electrode. However, being equal is not limited to exactly matching.

Although not shown, an optical adjustment layer for improving the light extraction efficiency and a sealing layer for protecting the display elements 21 and 22 from moisture and the like are provided on the upper electrodes E21 and E22.

Next, a method of manufacturing the display elements 21 and 22 having the structures described above will be described simply.

First, a processing substrate is prepared. The processing substrate is obtained by forming the lower electrodes E11 and E12 on the insulating layer 11 after forming the insulating layer 11 on the substrate 10, and then forming the insulating layer 12 which includes the opening OP1 overlapping the lower electrode E11 and the opening OP2 overlapping with the lower electrode E12.

After that, each layer constituting the organic layer OR is formed by vapor deposition. The vapor deposition of the organic layer OR is executed while the vapor deposition source is moved relatively to the processing substrate. In other words, the vapor deposition source may be moved with respect to the fixed processing substrate, the processing substrate may be moved with respect to the fixed vapor deposition source, or both the processing substrate and the vapor deposition source may be moved. For example, the direction of the movement is set to the first direction X in the layout of the sub-pixels shown in FIG. 3. The organic layers OR1 and OR2 are thereby formed at the openings OP1 and OP2, respectively. The end surfaces of the respective layers constituting the organic layer OR tend not to be aligned. In particular, each layer is likely to be exposed at the end surface (end surface SS shown in FIG. 3) that intersects with the direction of the movement.

After that, the upper electrode E2 is formed by, for example, vapor deposition or sputtering. At this time, the upper electrode E21 overlapping the organic layer OR1 is formed to expose the end surface SS1 of the organic layer OR1, and the upper electrode E22 overlapping the organic layer OR2 is formed to expose the end surface SS2 of the organic layer OR2. After that, the reflective layer RF is formed to fill the gap of the upper electrode E2. In other words, the reflective layer RF covers the end surface SS1 and the end surface SS2.

As described above, the light having a predetermined wavelength subjected to the resonance effect, of the light generated by the display elements 21 and 22 having a microcavity structure, is extracted, and the luminance and color purity of the display light can be improved. In addition, since the upper electrode does not overlap the end surface SS1 of the organic layer OR1 and the end surface SS2 of the organic layer OR2, emission of the light having an undesired wavelength which is not subjected to the resonance effect is suppressed. Furthermore, undesired current leakage between the end surface SS1 and the upper electrode E21 and between the end surface SS2 and the upper electrode E22 is suppressed. Therefore, the degradation in performance of the display element can be suppressed.

In addition, the reflective layer RF is provided in the gap between the upper electrode E21 and the upper electrode E22, which are transflective electrodes. Therefore, the reflective member is arranged over the entire area of the display portion DA, and the display device DSP with a desirable quality can be provided.

Next, another example will be described.

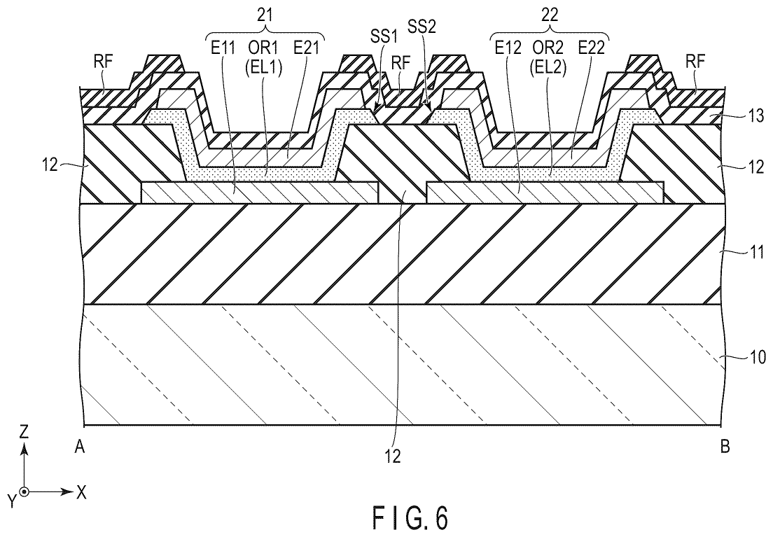

FIG. 6 is another cross-sectional view taken along line A-B shown in FIG. 4.

The example shown in FIG. 6 is different from the example shown in FIG. 5 in that the insulating film 13 is provided. The insulating film 13 covers the upper electrode E21 of the display element 21 and the upper electrode E22 of the display element 22. In addition, the insulating film 13 is in contact with the end surface SS1 of the organic layer OR1 and the end surface SS2 of the organic layer OR2. Furthermore, the insulating film 13 is in contact with the insulating layer 12 at a position between the end surfaces SS1 and SS2.

Such an insulating film 13 may be at least one layer that constitutes the optical adjustment layer or may be at least one layer that constitutes the sealing layer.

The reflective layer RF is arranged on the insulating film 13. Such a reflective layer RF may be an insulator or a conductor. When the reflective layer RF is a conductor, the reflective layer RF may be, for example, a touch detection line, a power supply line, a signal line, a ground line, or the like.

In another configuration example, too, the same advantages as those described above can be obtained.

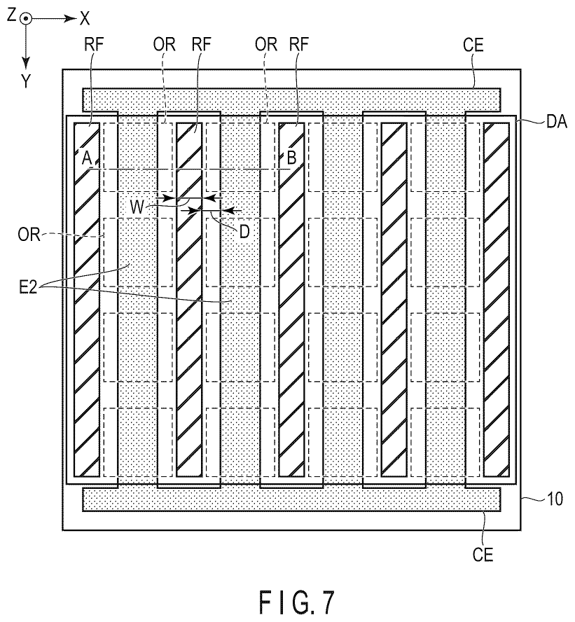

FIG. 7 is a plan view showing another example of the reflective layer RF which can be applied to the display portion DA shown in FIG. 3.

The example shown in FIG. 7 differs from the example shown in FIG. 4 in that the reflective layers RF do not overlap the upper electrode E2. The reflective layers RF are formed in a strip shape extending along the second direction Y and arranged at intervals in the first direction X, at the display portion DA. In plan view, the reflective layer RF is located between the upper electrodes E2 adjacent in the first direction X and does not overlap any of the upper electrodes E2. In addition, the reflective layer RF is located between the organic layers OR adjacent in the first direction X and does not overlap any of the organic layers OR.

From the viewpoint of making the gap between the reflective layer RF and the upper electrode E2 as inconspicuous as possible, a width W of the reflective layer RF along the first direction X is desirably larger than an interval D between the reflective layer RF and the upper electrode E2 along the first direction X at the display portion DA.

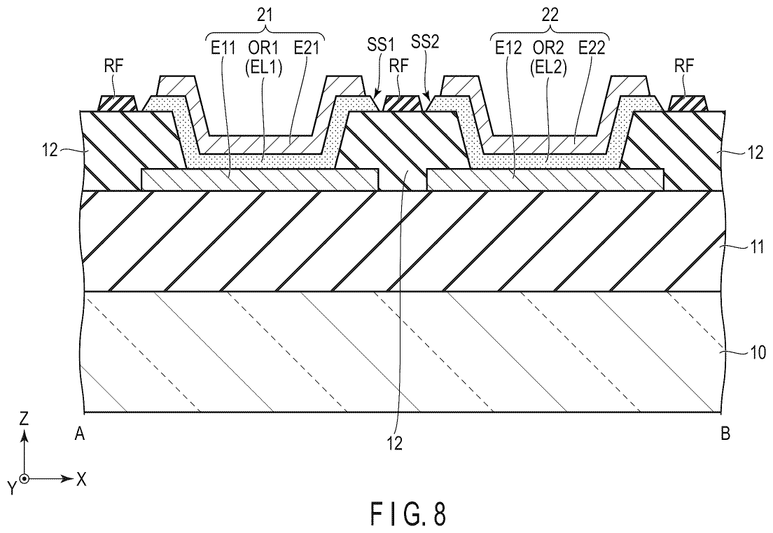

FIG. 8 is another cross-sectional view taken along line A-B shown in FIG. 7.

The reflective layer RF is separated from the upper electrodes E21 and E22 and the organic layers OR1 and OR2. The reflective layer RF is arranged on the insulating layer 12 between the end surface SS1 of the organic layer OR1 and the end surface SS2 of the organic layer OR2. Such a reflective layer RF may be an insulator or a conductor.

In another configuration example, too, the same advantages as those described above can be obtained.

According to the above-described embodiment, a display device with a desirable quality can be provided.

All of the display devices that can be realized by a person of ordinary skill in the art through arbitrary design changes to the display devices described above as embodiments of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device comprising:
a substrate;
a first lower electrode and a second lower electrode arranged on the substrate;
a first organic layer including a light emitting layer and arranged on the first lower electrode;
a second organic layer including a light emitting layer and arranged on the second lower electrode;
a first upper electrode arranged on the first organic layer;
a second upper electrode arranged on the second organic layer and separated from the first upper electrode; and
a reflective layer arranged between the first upper electrode and the second upper electrode.

2. The display device of claim 1, wherein
the first upper electrode and the second upper electrode are transflective electrodes and contain at least one of magnesium, silver, aluminum, and gold.

3. The display device of claim 1, wherein
the reflective layer has a first side surface overlapping the first upper electrode and a second side surface overlapping the second upper electrode.

4. The display device of claim 3, wherein
the reflective layer is an insulator which is in contact with the first upper electrode and the second upper electrode.

5. The display device of claim 4, wherein
the reflective layer is in contact with the first organic layer and the second organic layer.

6. The display device of claim 3, further comprising:
an insulating film covering the first upper electrode and the second upper electrode, wherein
the reflective layer is arranged on the insulating film.

7. The display device of claim 2, wherein
the reflective layer is separated from the first upper electrode, the second upper electrode, the first organic layer, and the second organic layer.

8. The display device of claim 7, wherein
a width of the reflective layer is larger than an interval between the first upper electrode and the reflective layer.
